(19) United States
(12) Patent Application Publication
(10) Pub. No.: US 2015/0162213 A1
(43) Pub. Date: Jun. 11, 2015

(54) FORMULATIONS FOR WET ETCHING NIPT DURING SILICIDE FABRICATION

(71) Applicant: ADVANCED TECHNOLOGY MATERIALS, INC., Danbury, CT (US)

(72) Inventors: Tianniu Chen, Westford, MA (US); Steven M. Bilodeau, Oxford, CT (US); Emanuel I. Cooper, Scarsdale, NY (US); Li-Min Chen, Norwalk, CT (US); Jeffrey A. Barnes, Bethlehem, CT (US); Mark Biscotto, Danbury, CT (US); Karl E. Boggs, Hopewell Junction, NY (US); Rekha Rajaram, White Plains, NY (US)

(73) Assignee: ADVANCED TECHNOLOGY MATERIALS, INC., Danbury, CT (US)

(21) Appl. No.: 14/400,456

(22) PCT Filed: May 10, 2013
(86) PCT No.: PCT/US2013/040517

§ 371 Date: Nov. 11, 2014

Related U.S. Application Data
(60) Provisional application No. 61/804,443, filed on Mar. 22, 2013.
(60) Provisional application No. 61/680,047, filed on Aug. 6, 2012.
(60) Provisional application No. 61/645,990, filed on May 11, 2012.

(51) Int. Cl. H01L 21/3213; C23F 1/30

(52) U.S. Cl. CPC H01L 21/32134; C23F 1/30

(57) ABSTRACT

Compositions and methods for substantially and efficiently removing NiPt (1-25%) material from microelectronic devices having same thereon. The compositions are substantially compatible with other materials present on the microelectronic device such as gate metal materials.

### CROSS REFERENCE TO RELATED APPLICATIONS

This application claims priority to U.S. Provisional Patent Application No. 61/645,990 filed May 11, 2012 in the name of Steven M. Bilodeau et al. entitled “Formulations for Wet Etching NiPt During Silicide Fabrication,” to U.S. Provisional Patent Application No. 61/804,443 filed Mar. 22, 2013 in the name of Steven M. Bilodeau et al. entitled “Formulations for Wet Etching NiPt During Silicide Fabrication,” and to U.S. Provisional Patent Application No. 61/680,047 filed Aug. 6, 2012 in the name of Emanuel I. Cooper et al. entitled “Formulations for Wet Etching NiPt During Silicide Fabrication, each of which is incorporated by reference herein in their entirety.

### FIELD

The present invention relates generally to compositions for substantially and efficiently removing a NiPt (1-25%) material from microelectronic devices having same thereon, wherein the compositions are substantially compatible with other materials such as gate metal materials.

### DESCRIPTION OF THE RELATED ART

Nickel silicide (NiSi) has been used in CMOS device fabrication to form stable ohmic contacts between silicon and metallic conductors. To reduce resistivity and improve thermal stability and film morphology 1-25% Pt can be added to the Ni before silicide formation. The current process flow starts with a patterned wafer with areas of exposed silicon. A blanket film of NiPt (1-25% Pt) is deposited on this structure and annealed at 250-350° C. During this anneal some the NiPt reacts with the underlying Si to form a silicide. The unreacted NiPt is then removed with a wet etch step. In the regions where Si was not exposed the full thickness of NiPt is removed, resulting in a silicide that is only present where the silicon was initially exposed. A second high temperature anneal (>400° C.) is used to insure that a stable low resistivity monosilicide (NiₓPt₁₋ₓSi) is formed.

Traditional wet etching formulations use either concentrated HO/nitric acid mixtures or concentrated sulfuric acid/hydrogen peroxide mixtures to etch the NiPt layer. Concentrated HCl/nitric acid mixtures tend to pit the silicide resulting in higher sheet resistance with a broad distribution (M. Chu et al., MAP 49(2010), 06GG16). Both of these approaches will rapidly etch any exposed gate metals (e.g., TiN, Al, W). Since these gate metals are sometimes exposed due to slight misalignment of the lithography during manufacturing, it is desirable to have wet etching solutions that do not etch these layers.

Accordingly, it is an object of the present invention to provide a composition that selectively removes a NiPt (1-25%) material, while not substantially removing other layers that may be present on the surface of the microelectronic device.

### SUMMARY

The present invention generally relates to a composition and process for the at least partial removal of a NiPt (1-25%) material from microelectronic devices having said material thereon. The compositions are formulated to be substantially compatible with other materials such as gate metal materials.

In one aspect, a method of removing NiPt (1-25% Pt) from a microelectronic device comprising same is described, said method comprising contacting the NiPt (1-25% Pt) with a composition to at least partially remove the NiPt (1-25%), wherein the composition comprises at least one oxidizing agent, at least one complexing agent, and at least one solvent.

Other aspects, features and advantages will be more fully apparent from the ensuing disclosure and appended claims.

### BRIEF DESCRIPTION OF THE DRAWINGS

FIG. 1 illustrates the Pourbaix diagram for Pt in water.

### DETAILED DESCRIPTION, AND PREFERRED EMBODIMENTS THEREOF

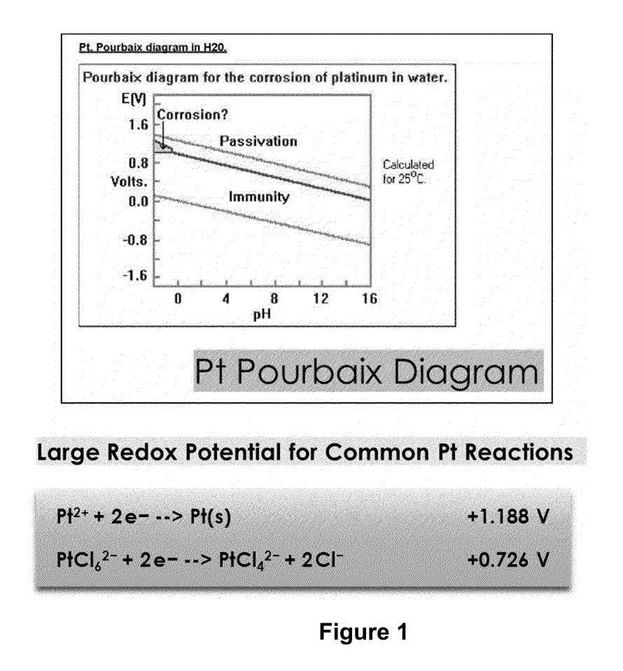

The relative inertness of Pt is the fundamental barrier to efficient removal of a NiPt (1-25%) material. The Pourbaix diagram for Pt in H₂O is shown in FIG. 1. There is only a small region at pH approximately 0 and potential approximately 1.0 where dissolution of Pt is thermodynamically favorable. These extreme conditions make compatibility with other materials difficult. Knowing this, the present inventors chose to use a strong acid with a strong oxidizer so as to operate near this region, and include Pt complexing agents. The addition of complexing agents that form stable, soluble Pt complexes and allow dissolution of Pt under a broader range of conditions. Importantly, the combination of strong acid/oxidizer/complexing agent preferably removes NiPt (1-25% Pt) material with minimal etching of gate metal materials. The performance of these formulations can be further improved by addition of corrosion inhibitors to suppress etching of said gate metals.

For ease of reference, “microelectronic device” corresponds to semiconductor substrates, flat panel displays, phase change memory devices, solar panels and other products including solar cell devices, photovoltaics, and microelectromechanical systems (MEMS), manufactured for use in microelectronic, integrated circuit, energy collection, or computer chip applications. It is to be understood that the terms “microelectronic device,” “microelectronic substrate” and “microelectronic device material” are not meant to be limiting in any way and include any substrate or structure that will eventually become a microelectronic device or microelectronic assembly.

The meaning of “metal gate” or “metal gate electrode,” as used herein, includes gate electrodes of transistors (e.g., FET) comprising metal. The metal may be in combination with other material. Metals in the metal gates include, but are not limited to, Ti, Ta, W, Mo, Ru, Al, La, titanium nitride, tantalum nitride, tantalum carbide, titanium carbide, molybdenum nitride, tungsten nitride, ruthenium (IV) oxide, tantalum silicon nitride, titanium silicon nitride, tantalum carbon nitride, titanium carbon nitride, titanium aluminide, tantalum aluminide, titanium aluminum nitride, tantalum aluminum nitride, lanthanum oxide, or combinations thereof. One specific example of a metal gate comprises titanium nitride (TiN). It is noted that TiN has other uses in electronic devices, for example, as a barrier metal between silicon and metal contacts and as an electric conductor. It should be appreciated that the compounds disclosed as metal gate materials may have varying stoichiometries. Accordingly, titanium nitride will be represented as TiN_{X} herein, tantalum nitride will be represented as TaNₓ herein, and so on, wherein x can be any value greater than zero.

“Silicon” may be defined to include, Si, polycrystalline Si, monocrystalline Si, and SiGe as well as other silicon-containing materials such as silicon oxide, silicon nitride, thermal oxide, SiOH and SiCOH. Silicon is comprised in silicon-on-insulator (SOI) wafers that may be used, for example, as substrates or part of a substrate for electronic devices such as FETs and integrated circuits. Other types of wafers may also comprise silicon.

As defined herein, “complexing agent” includes those compounds that are understood by one skilled in the art to be complexing agents, chelating agents, sequestering agents, and combinations thereof. Complexing agents will chemically combine with or physically associate with the metal atom and/or metal ion to be removed using the compositions described herein.

“Substantially devoid” is defined herein as less than 2 wt. %, preferably less than 1 wt. %, more preferably less than 0.5 wt. %, even more preferably less than 0.1 wt. %, and most preferably 0 wt %.

As used herein, “about” is intended to correspond to ±5% of the stated value.

It is well understood to the skilled artisan that “iodine” corresponds to the I₂ molecule while “iodide” (I−) is an anion and is provided as a salt.

As used herein, “chloride” species correspond to species including an ionic chloride (Cl⁻), with the proviso that surfactants that include chloride anions are not considered “chlorides” according to this definition. As used herein, “bromide” species correspond to species including an ionic bromide (Br), with the proviso that surfactants that include bromide anions are not considered “bromide” according to this definition. Examples of surfactants that include bromide or chloride anions include, but are not limited to, cetyl trimethylammonium bromide (CTAB), stearyl trimethylammonium chloride (Econol TMS-28, Sanyo), 4-(4-di ethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, do decyltrimethylammonium chloride, didodecyldimethylammonium bromide, di(hydrogenated tallow)dimethylammonium chloride, tetraheptylammonium bromide, tetrakis(decyl)ammonium bromide, oxyphenonium bromide, guanidine hydrochloride (C(NH₂)₃Cl), dimethyldioctadecylammonium chloride, dimethyldihexadecylammonium bromide, myristyltrimethylammonium bromide, 1-methyl-3-octylimidazolium bromide, di(hydrogenated tallow)dimethylammonium chloride (e.g., Arquad 2HT-75, Akzo Nobel).

For ease of reference, a “NiPt (1-25%) material” corresponds to any alloy including Ni and Pt in varying amounts, most often having 1-25% Pt. It should be appreciated that the NiPt (1-25%) material can include other elements, for example, wherein the nickel is partially substituted by cobalt and/or the platinum is partially substituted by other noble metals (e.g., Pd, Rh, Ir, Ru, and Re). It should be appreciated that the NiPt (1-25%) material does not include the silicided NiPt (1-25%) material (i.e., (NiₓPt₁₋ₓSi)), which the composition described herein is not intended to remove.

Compositions described herein may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

In a first aspect, a composition for etching NiPt (1-25% Pt) is described, said composition comprising, consisting of, or consisting essentially of at least one acid, at least one oxidizing agent, and at least one complexing agent. The composition effectively and efficiently removes NiPt (1-25% Pt) material from the surface of a microelectronic device having same thereon without substantially removing other materials present on the microelectronic device such as metal gate materials (e.g., TiN, Al and W) and silicided NiPt (i.e., NiₓPt₁₋ₓSi). In one embodiment, the composition comprises, consists of, or consists essentially of at least one acid, at least one oxidizing agent, at least one complexing agent, and at least one solvent. In another embodiment, the composition comprises, consists of, or consists essentially of at least one acid, at least one oxidizing agent, at least one complexing agent, at least one solvent, and at least one corrosion inhibitor. In still another embodiment, the composition comprises, consists of, or consists essentially of at least one acid, at least one oxidizing agent, at least one complexing agent, at least one monosaccharide or polysaccharide, and at least one solvent. In yet another embodiment, the composition comprises, consists of, or consists essentially of at least one acid, at least one oxidizing agent, at least one complexing agent, at least one solvent, at least one monosaccharide or polysaccharide, and at least one corrosion inhibitor.

Acids contemplated include inorganic acids such as nitric acid, hydrochloric acid, sulfuric acid, hydrobromic acid, hydroiodic acid, perchloric acid, and combinations thereof. Alternatively, or in addition to, the acids can be organic acids such as phosphoric acids, methanesulfonic acid, phosphonic acids, and combinations thereof, wherein the phosphonic acids have the formula (R¹)(R²)P(═O)(R³), wherein R¹, R² and R³ can be the same as or different from one another and are selected from the group consisting of hydrogen, hydroxyl, C₁-C₃₀ alkyls, C₂-C₃₀ alkenes, cycloalkyls, C₂-C₃₀ alkoxys, or any combination thereof, including but not limited to, 1-hydroxyethane 1,1-diphosphonic acid (HEDP), decylphosphonic acid, dodecylphosphonic acid (DDPA), tetradecylphosphonic acid, hexadecylphosphonic acid, bis(2-ethylhexyl)phosphate, octadecylphosphonic acid, and combinations thereof. Preferably, the acid comprises hydrochloric acid, sulfuric acid or methanesulfonic acid.

Oxidizing agents contemplated include bromine, ozone, nitric acid, bubbled air, cyclohexylaminosulfonic acid, hydrogen peroxide (H₂O₂), FeCl₃ (both hydrated and unhydrated), oxone (2KHSO₅.KHSO₄.K₂SO₄), oxone tetrabutylammonium salt, iodic acid, periodic acid, permanganic acid, chromium (III) oxide, ammonium cerium nitrate, methylmorpholine-N-oxide, trimethylamine-N-oxide, triethylamine-N-oxide, pyridine-N-oxide, N-ethylmorpholine-N-oxide, N-methylpyrrolidine-N-oxide, N-ethylpyrrolidine-N-oxide, nitroaromatic acids such as Nitrobenzoic acids ammonium polyatomic salts (e.g., ammonium peroxomonosulfate, ammonium chlorite (NH₄ClO₂), ammonium chlorate (NH₄ClO₃), ammonium iodate (NH₄IO₃), ammonium perborate (NH₄BO₃), ammonium perchlorate (NH₄ClO₄), ammonium periodate (NH₄IO₃), ammonium persulfate ((NH₄)₂S₂O₈), ammonium hypochlorite (NH₄ClO)), sodium polyatomic salts (e.g., sodium persulfate (Na₂S₂O₈), sodium hypochlorite (NaClO)), potassium polyatomic salts (e.g., potassium iodate (KIO₃), potassium permanganate (KMnO₄), potassium persulfate, nitric acid (HNO₃), potassium persulfate (K₂S₂O₈), potassium hypochlorite (KClO)), tetramethylammonium polyatomic salts (e.g., tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈)), tetrabutylammonium polyatomic salts (e.g., tetrabutylammonium peroxomonosulfate), peroxomonosulfuric acid, ferric nitrate (Fe(NO₃)₃), urea hydrogen peroxide ((CO(NH₂)₂)H₂O₂), peracetic acid (CH₃(CO)OOH), sodium nitrate, potassium nitrate, ammonium nitrate, sulfuric acid, chlorine, chlorine dioxide, and combinations thereof.

Alternatively, or in addition to, the at least one oxidizing agent can include N-haloimides such as N-chlorosuccinimide, N-bromosuccinimide, N-halophthlamides, N-haloglutarimides, N-halosulfonamides (e.g., N,N-dichlorobenzenesulfonamide, N,N-dichlorotoluenesulfonamide, N-chlorobenzenesulfonamide, N-chlorotoluenesulfonamide), and combinations thereof. Preferably, the oxidizing agent comprises sulfuric acid, bromosuccinimide, chlorosuccinimide, combinations of bromosuccinimide and chlorosuccinimide, or ammonium persulfate.

Advantageously, when the oxidizing agent comprises bromosuccinimide, since bromosuccinimide can be produced by reacting succinimide to bromine in an acidic solution (in the presence of HBr), it is possible to fine-tune the activity and solution stability by adding succinimide.

It should be appreciated that when nitric acid or sulfuric acid is the acid, it can be the oxidizing agent as well. Accordingly, in another embodiment, the composition of the first aspect comprises, consists of, or consists essentially of nitric acid or sulfuric acid, at least one complexing agent, and at least one solvent. In still another embodiment, the composition of the first aspect comprises, consists of, or consists essentially of nitric acid or sulfuric acid, at least one complexing agent, at least one solvent, and at least one corrosion inhibitor.

The complexing agents are included to complex the ions produced by the oxidizing agent. Complexing agents contemplated herein include, but are not limited to: β-diketonate compounds such as acetylacetonate, 1,1,1-trifluoro-2,4-pentanedione, and 1,1,1,5,5,5-hexafluoro-2,4-pentanedione; carboxylates such as formate and acetate and other long chain carboxylates; and amides (and amines), such as bis(trimethylsilylamide) tetramer. Additional complexing agents include amines and amino acids (i.e. glycine, serine, proline, leucine, alanine, asparagine, aspartic acid, glutamine, valine, and lysine), citric acid, acetic acid, maleic acid, oxalic acid, malonic acid, succinic acid, phosphonic acid, phosphonic acid derivatives such as hydroxyethylidene diphosphonic acid (HEDP), 1-hydroxyethane-1,1-diphosphonic acid, nitrilo-tris(methylenephosphonic acid), iminodiacetic acid (IDA), etidronic acid, ethylenediamine, ethylenediaminetetraacetic acid (EDTA), and (1,2-cyclohexylenedinitrilo)tetraacetic acid (CDTA), uric acid, tetraglyme, pentamethyldiethylenetriamine (PMDETA), 1,3,5-triazine-2,4,6-thithiol trisodium salt solution, 1,3,5-triazine-2,4,6-thithiol triammonium salt solution, sodium diethyldithiocarbamate, disubstituted dithiocarbamates (R¹(CH₂CH₂O)₂NR²CS₂Na) with one alkyl group (R²=hexyl, octyl, deceyl or dodecyl) and one oligoether (R¹(CH₂CH₂O)₂, where R¹=ethyl or butyl), ammonium sulfate, monoethanolamine (MEA), Dequest 2000, Dequest 2010, Dequest 2060s, diethylenetriamine pentaacetic acid, propylenediamine tetraacetic acid, 2-hydroxypyridine 1-oxide, ethylendiamine disuccinic acid (EDDS), N-(2-hydroxyethyl)iminodiacetic acid (HEIDA), sodium triphosphate penta basic, sodium and ammonium salts thereof, ammonium sulfate, hydrochloric acid, sulfuric acid, dimethylglyoxime, and combinations thereof. Alternatively, or in addition to, the complexing agent can comprise halides (e.g., ammonium chloride, ammonium bromide, sodium chloride, lithium chloride, potassium chloride), sulfonates, nitrates, sulfates, organic sulfonic acids with formula as RS(═O)(═O)OH, where R is selected from but not limited to the group consisting of hydrogen, C₂-C₃₀ alkyls, C₂-C₃₀ alkenes, cycloalkyls, C₂-C₃₀ alkoxys, C₂-C₃₀ carboxyls (e.g., methanesulfonic acid (MSA), ethanesulfonic acid, 2-hydroxyethanesulfonic acid, n-propanesulfonic acid, isopropanesulfonic acid, isobutenesulfonic acid, n-butanesulfonic acid, and n-octanesulfonic acid), and combinations thereof. Preferably the complexing agent comprises ammonium chloride, ammonium bromide, iminodiacetic acid, or a combination thereof.

Solvents contemplated include, but are not limited to, water, alcohols, alkylenes, silyl halides, carbonates (e.g., alkyl carbonates, alkylene carbonates, etc.), glycols, glycol ethers, hydrocarbons, hydrofluorocarbons, and combinations thereof, such as straight-chained or branched methanol, ethanol, isopropanol, butanol, pentanol, hexanol, 2-ethyl-1-hexanol, heptanol, octanol, and higher alcohols (including diols, triols, etc.), 4-methyl-2-pentanol, ethylene glycol, propylene glycol, butylene glycol, butylene carbonate, ethylene carbonate, propylene carbonate, dipropylene glycol, glycol ethers (e.g., diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether), 2,3-dihydrodecafluorpentane, ethyl perfluorobutyl ether, methyl perfluorobutyl ether, and combinations thereof. In one embodiment, one of the solvents has the formula R¹R²R³C(OH), where R1, R² and R³ are the same as or different from each other and are selected from to the group consisting of hydrogen, C₂-C₃₀ alkyls, C₂-C₃₀ alkenes, cycloalkyls, C₂-C₃₀ alkoxys, and combinations thereof. Preferably, the at least one solvent comprises water, 4-methyl-2-pentanol, TPGME, octanol, 2-ethyl-1-hexanol, isopropanol, and any combination thereof. The concentration of solvent in the composition is preferably in a range from about 10 wt % to about 99.9 wt. %, more preferably in a range from about 50 wt. % to about 99.9 wt. %, and most preferably in a range from about 90 wt. % to about 99.9 wt. %.

When present, the preferred corrosion inhibitors include, but are not limited to, ascorbic acid, adenosine, L(+)-ascorbic acid, isoascorbic acid, ascorbic acid derivatives, citric acid, ethylenediamine, gallic acid, oxalic acid, tannic acid, aspartic acid, ethylenediaminetetraacetic acid (EDTA), uric acid, 1,2,4-triazole (TAZ), triazole derivatives (e.g., benzotriazole (BTA), tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), 4-Amino-4H-1,2,4-triazole (ATAZ), naphthotriazole), 2-mercaptobenzimidazole (MBI), 2-ethyl-4-methylimidazole, 2-mercaptobenzothiazole, 4-methyl-2-phenylimidazole, 2-mercaptothiazoline, 5-aminotetrazole (ATA), 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, benzoic acid, boric acid, malonic acid, ammonium benzoate, catechol, pyrogallol, resorcinol, hydroquinone, cyanuric acid, barbituric acid and derivatives such as 1,2-dimethylbarbituric acid, alpha-keto acids such as pyruvic acid, adenine, purine, phosphonic acid and derivatives thereof, glycine/ascorbic acid, Dequest 2000, Dequest 7000, p-tolylthiourea, succinic acid, phosphonobutane tricarboxylic acid (PBTCA), benzylphosphonic acid, and combinations thereof. Alternatively, or in addition to, the corrosion inhibitors include compounds having the general formula R¹R²NC(═NR³)(NR⁴)(CH2)ₙC(NR⁵R⁶)R⁷R⁸, where R1, R², R³, R⁴, R⁵, R⁶, R⁷ and R⁸ can be the same as or different from each other and are selected from to the group consisting of hydrogen, C₂-C₃₀ alkyls, C₂-C₃₀ alkenes, cycloalkyls, C₂-C₃₀ alkoxys, C₂-C₃₀ carboxyls and combinations thereof, n is an integer from 1-6 such as arginine. Cationic surfactants are also contemplated as corrosion inhibitors including, but not limited to, heptadecanefluorooctane sulfonic acid tetraethylammonium, stearyl trimethylammonium chloride (Econol TMS-28, Sanyo), 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, hexadecyltrimethylammonium p-toluenesulfonate, didodecyldimethylammonium bromide, di(hydrogenated tallow)dimethylammonium chloride, tetraheptylammonium bromide, tetrakis(decyl)ammonium bromide, Aliquat® 336 and oxyphenonium bromide, guanidine hydrochloride (C(NH₂)₃Cl) or triflate salts such as tetrabutylammonium trifluoromethanesulfonate. The hydrocarbon groups preferably have at least 10, e.g., 10-20, carbon atoms (e.g., decyl, undecyl, dodecyl, tridecyl, tetradecyl, pentadecyl, hexadecyl, heptadecyl, octadecyl, nonadecyl, eicosyl), except that somewhat shorter hydrocarbon groups of 6-20 carbons (e.g. hexyl, 2-ethylhexyl, dodecyl) are preferred where the molecule contains two functionalized alkyl chains such as in dimethyldioctadecylammonium chloride, dimethyldihexadecylammonium bromide and di(hydrogenated tallow)dimethylammonium chloride (e.g., Arquad 2HT-75, Akzo Nobel). Preferably, dimethyldioctadecylammonium chloride, di(hydrogenated tallow)dimethylammonium chloride, or a combination thereof is used. Further, carboxylic acids with formula (R¹)₃₋ₘN[(CH2)nC(═O)OH]ₘ, where R¹ includes groups selected from, but not limited to, hydrogen, alkyls, carboxylic groups, amido groups and combinations thereof, n is an integer from 1-6, and m is an integer from 1-3, such as iminoacetic acid, iminodiacetic acid, N-(2-Acetamido)iminodiacetic acid, and nitrilotriacetic acid. Preferably, the corrosion inhibitor comprises a phosphonic acid such as benzylphosphonic acid.

Minimizing the attack on NiPt silicide, which typically lies underneath the NiPt residues being etched, can be difficult, since the etching composition tends to leach Ni and especially Pt out of the silicide when the NiPt covering it is gone. The silicide can be protected by optimizing process conditions, e.g., reducing temperature and acid content as well as adding inhibitors that bind selectively to silicon oxide, e.g., hydrophillic non-ionic surfactants, sugar alcohols or water-soluble solvents based on glycol ethers. The addition of mild oxygen-containing oxidants may also help limit the attack on silicide, for example dilute nitric acid, pyridinium N-oxide, N-methylmorpholinium N-oxide, nitro- and dinitrophenols and isatin. Accordingly, the compositions of the first aspect can further include at least one additional species selected from the group consisting of hydrophillic non-ionic surfactants, sugar alcohols, water-soluble solvents based on glycol ethers, mild oxygen-containing oxidants, and combinations thereof. Non-ionic surfactants contemplated include, but are not limited to, polyoxyethylene lauryl ether (Emalmin NL-100 (Sanyo), Brij 30, Brij 98), dodecenylsuccinic acid monodiethanol amide (DSDA, Sanyo), ethylenediamine tetrakis (ethoxylate-block-propoxylate) tetrol (Tetronic 90R4), polyoxyethylene polyoxypropylene glycol (Newpole PE-68 (Sanyo), Pluronic L31, Pluronic 31R1), polyoxypropylene sucrose ether (SN008S, Sanyo), t-octylphenoxypolyethoxyethanol (Triton X100), Polyoxyethylene (9) nonylphenylether, branched (IGEPAL CO-250), polyoxyethylene sorbitol hexaoleate, polyoxyethylene sorbitol tetraoleate, polyethylene glycol sorbitan monooleate (Tween 80), sorbitan monooleate (Span 80), alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives such as SIS6952.0 (Siliclad, Gelest), siloxane modified polysilazane such as PP1-SG10 Siliclad Glide 10 (Gelest), silicone-polyether copolymers such as Silwet L-77 (Setre Chemical Company), Silwet ECO Spreader (Momentive), and alcohol ethoxylates (NatsurfrM 265, Croda). Sugar-alcohols include erythritol, xylitol, mannitol, sorbitol, glycerol or maltitol. Glycol ethers were defined above.

The compositions may further comprise at least one monosaccharide or polysaccharide, such as glucose, fructose, ribose, mannose, galactose, sucrose, lactose or raffinose.

The compositions of the first aspect have pH in a range from about −1 to about 7, preferably about −1 to about 4. Further, the compositions of the first aspect are preferably substantially devoid of chemical mechanical polishing abrasive, hydrogen peroxide, and combinations thereof. When the composition of the first aspect includes sulfuric acid, the composition is preferably substantially devoid of a nitrate or nitrosyl ion (e.g., nitric acid, nitrous acid, nitrosyl tetrafluoroborate, a nitrosyl halide, a nitrite salt, an organic nitrite compound). When the composition of the first aspect includes a sulfonic acid and a chloride salt (e.g., ammonium chloride), the composition is preferably substantially devoid of a nitrogen oxide compound (e.g., nitric acid, ammonium nitrate, quaternary ammonium nitrates, phosphonium nitrates, metal nitrates).

In a preferred embodiment, the composition of the first aspect comprises, consists of, or consists essentially of 5-30 wt % sulfuric acid, 1-10 wt % ammonium chloride, and 60-94 wt % water. In another preferred embodiment, the composition of the first aspect comprises, consists of, or consists essentially of 5-30 wt % sulfuric acid, 1-10 wt % ammonium chloride, 0.01-0.5 wt % IDA, and 60-93.5 wt % water. In yet another preferred embodiment, the composition of the first aspect comprises, consists of, or consists essentially of 5-30 wt % sulfuric acid or ammonium persulfate, 1-10 wt % ammonium chloride, 0.01-0.5 wt % IDA, 1-20 wt % monosaccharide or polysaccharide, and 40-92.5 wt % water.

In a second aspect, a NiPt (1-25%) etching composition based on the halogens and/or interhalogen compounds is described, wherein said composition is compatible with gate metals (e.g., W, TiN and Al). In general, the halogen and/or interhalogen compound (i.e., the oxidizing agent) is paired with a halide ion (i.e., a complexing agent) so that the latter will not be oxidized to a substantial extent by the former, unless such oxidation is expressly desirable. Considered another way, the etching composition of the second aspect comprises, consists, or consists essentially of at least one complexing source (i.e., at least one halide ion salt), at least one oxidizing agent (i.e., halogen and/or interhalogen compound), and at least one solvent. In another embodiment, the etching composition of the second aspect comprises, consists, or consists essentially of at least one complexing source (i.e., at least one halide ion salt), at least one oxidizing agent (i.e., halogen and/or interhalogen compound), at least one acid, and at least one solvent. The composition effectively and efficiently removes NiPt (1-25% Pt) material from the surface of a microelectronic device having same thereon without substantially removing other materials present on the microelectronic device such as metal gate materials (e.g., TiN, Al and W) and silicided NiPt (i.e., NiₓPt₁₋ₓSi). The compositions of the second aspect have pH in a range from about −1 to about 7, preferably about −1 to about 4. Further, the compositions of the second aspect are preferably substantially devoid of chemical mechanical polishing abrasive, hydrogen peroxide, and combinations thereof.

In one embodiment of the second aspect, the oxidizing agent/complexing agent combination can be IBr in excess bromide or chloride to form IBr₂⁻ or IBrCl⁻, respectively. In a second embodiment of the second aspect, the oxidizing agent/complexing agent combination is ICl in excess chloride or bromide to form ICl₂⁻ or IBrCl⁻, respectively. In a third embodiment of the second aspect, the oxidizing agent/complexing agent combination is bromine (Br₂) in excess bromide or chloride to form the Br₃⁻ or Br₂Cl⁻, respectively. For the excess bromide or chloride ion, the most preferred compounds are ammonium halide salts or hydrogen halides (e.g., NH₄Cl, NH₄Br, HCl, HBr). However, many other compounds can be used, in particular organic halide salts such as quaternary ammonium halides. Quaternary ammonium halides include compounds having the formula (NR¹R²R³R⁴)⁺X⁻, wherein X is Cl or Br, and R¹, R², R³ and R⁴ may be the same as or different from one another and are selected from the group consisting of hydrogen, straight-chained or branched C₁-C₆ alkyl (e.g., methyl, ethyl, propyl, butyl, pentyl, and hexyl), and substituted or unsubstituted C₆-C₁₀ aryl, e.g., benzyl, with the proviso at least one of R¹, R², R³ or R⁴ has to be a component other than hydrogen. When a salt is used, it can be added as such or generated in situ from its acidic and basic components.

In a fourth embodiment of the second aspect, the oxidizing agent/complexing agent combination is elemental iodine in excess iodide, wherein the at least one iodide species includes, but is not limited to, ammonium iodide, iodic acid (HI), potassium iodide, sodium iodide, and quaternary ammonium iodide having the formula NR¹R²R³R⁴I, wherein R¹, R², R³ and R⁴ may be the same as or different from one another and are selected from the group consisting of hydrogen, straight-chained or branched C₁-C₆ alkyl (e.g., methyl, ethyl, propyl, butyl, pentyl, and hexyl), and substituted or unsubstituted C₆-C₁₀ aryl, e.g., benzyl, with the proviso at least one of R¹, R², R³ or R⁴ has to be a component other than hydrogen. Preferably, the at least one iodide species comprises ammonium iodide. The combination of iodine and iodide forms triiodide which readily reacts with the platinum.

The halogen and/or interhalogen compound can be added to the formulation as such, or it can be generated in situ by oxidation of halide salts or acids. For example, elemental Br₂ can be added to an ammonium bromide solution. Alternatively, a strong oxidant such as ammonium persulfate or ammonium iodate can be used to generate the oxidizer in situ. For example, ammonium persulfate in an amount equivalent to the desired amount of Br₂ can be added to the ammonium bromide solution and the solution heated for about 1 h at 65° C. or allowed to stay at room temperature for about 24 h, whereby essentially all the ammonium persulfate reacts with the bromide salt or HBr and generates Br₂, which is largely complexed by the excess salt to form Br₃⁻.

Another way to add the halogen and/or interhalogen compound to the composition is by means of a salt that has the trihalide ion as its anion. Examples include, but are not limited to: tetrabutylammonium tribromide, pyridinium tribromide, trimethylphenylammonium tribromide, 2-pyrrolidinone hydrotribromide, benzyltrimethylammonium dichloroiodate, tetramethylammonium dichloroiodate, 1-butyl-3-methylimidazolium tribromide. In these cases the initial molar ratio of halogen to halide is intrinsically 1:1. Additional halide in the form of, e.g., ammonium halide or hydrogen halide, can be used in order to supply a larger excess and shift the halogen+halide⇄trihalide equilibrium to the extent desired. The excess halide ion complexes the halogen and/or interhalogen compound and thus increase its solubility in water and drastically reduce its volatility. The excess halide also complexes the dissolved metal ions, especially platinum, thus lowering the metal oxidation potential.

When present, the at least one acid can be selected from the group consisting of methanesulfonic acid, oxalic acid, sulfuric acid, nitric acid, HCl, HBr, HI, citric acid, tartaric acid, picolinic acid, succinic acid, acetic acid, lactic acid, sulfosuccinic acid, benzoic acid, propionic acid, formic acid, oxalic acid, maleic acid, malonic acid, fumaric acid, malic acid, ascorbic acid, mandelic acid, heptanoic acid, butyric acid, valeric acid, glutaric acid, and phthalic acid and combinations thereof.

While the halide ion is used as a complexing agent for the composition of the second aspect, it need not be the only one in the formulation. Additional complexing agents can be added including, but not limited to, oxalic acid, picolinic acid, bipyridyl, 1,5-cyclooctadiene (in solvent-containing formulations), thiocyanates, and thiodiglycolic acid. As will be obvious to those skilled in the art, useful components that react slowly with other formulation components (e.g., in redox reactions) are preferably added at the point of use.

The solvent that serves as the reaction medium for the composition of the second aspect is typically water, or a mixture of water and a polar organic solvent. Water has the advantage of simplicity, low cost, and high solubility of salts. The addition of an organic polar solvent, e.g., acetic acid, an alcohol, or sulfolane, helps to stabilize interhalogen complexes and thus increases the solubility and reduces the volatility of the halogens and halogen compounds, and also reduces their tendency to infiltrate, stain and possibly attack some plastic materials. In addition, the organic solvent can solubilize some organic additives, lower the contact angle of the formulation with film surfaces, and help remove organic residues or contaminants. Alternatively, or in addition to, the at least one solvent can include one of the solvents introduced with regards to the composition of the first aspect. Preferably, the solvent of the composition of the second aspect is water and is present in an amount of greater than 80 wt %, more preferably in a range from 80 wt % to 95 wt %, based on the total weight of the composition.

The compositions of the second aspect can further include at least one additional species selected from the group consisting of at least one corrosion inhibitor, at least one glycol ether, at least one surfactant, and combinations thereof.

Preferably, the composition of the second aspect comprises, consists of, or consists essentially of bromosuccinimide, chlorosuccinimide, ammonium chloride, ammonium bromide, water, and one of sulfuric acid or methanesulfonic acid. In another preferred embodiment, the composition of the second aspect comprises, consists of, or consists essentially of bromosuccinimide, chlorosuccinimide, ammonium bromide, water, and one of sulfuric acid or methanesulfonic acid. In still another preferred embodiment, the composition of the second aspect comprises, consists of, or consists essentially of bromosuccinimide, chlorosuccinimide, ammonium chloride, water, and one of sulfuric acid or methanesulfonic acid. In yet another preferred embodiment, the composition of the second aspect comprises, consists of, or consists essentially of bromosuccinimide, ammonium chloride, ammonium bromide, water, and one of sulfuric acid or methanesulfonic acid. In another preferred embodiment, the composition of the second aspect comprises, consists of, or consists essentially of bromine, ammonium chloride, ammonium bromide, water, and one of sulfuric acid or methanesulfonic acid.

Depending on the presence of other particular materials, either exposed or having the potential to become exposed (e.g. by lithography misalignment), at least one corrosion inhibitor can be added to the etching composition of the second aspect. Aluminum and TiN can be further protected by including a phosphonic acid inhibitor, e.g. phosphonic acid, phosphonic acid derivatives such as hydroxyethylidene diphosphonic acid (HEDP), 1-hydroxyethane-1,1-diphosphonic acid, nitrilo-tris(methylenephosphonic acid), or benzylphosphonic acid. Tungsten protection can be achieved by adding a long-chain quaternary ammonium compound such as benzalkonium chloride or myristyltrimethylammonium bromide, or a 1,3-dialkylimidazolium compound such as 1-methyl-3-octylimidazolium bromide. Alternatively, or in addition to, the at least one corrosion inhibitor can include one of the corrosion inhibitors introduced with regards to the composition of the first aspect.

Minimizing the attack on NiPt silicide, which typically lies underneath the NiPt residues being etched, can be difficult, since the etching composition tends to leach Ni and especially Pt out of the silicide when the NiPt covering it is gone. The silicide can be protected by optimizing process conditions, e.g., reducing temperature and acid content as well as adding inhibitors that bind selectively to silicon oxide, e.g., hydrophillic non-ionic surfactants, sugar alcohols or water-soluble solvents based on glycol ethers, as described hereinabove. The addition of mild oxygen-containing oxidants may also help limit the attack on silicide, as described hereinabove.

In a preferred embodiment of the second aspect, elemental iodine can be the oxidizing agent, ammonium iodide can be the complexing source, and methanesulfonic acid (MSA) can be the acid. Alternatively, elemental iodine can be the oxidizing agent, ammonium iodide can be the complexing source, and oxalic acid can be the acid.

The compositions of the second aspect are preferably substantially devoid of chemical mechanical polishing abrasive, hydrogen peroxide, and combinations thereof.

An advantage of the compositions of the second aspect is that when the pH is low, they cause much less damage to tungsten. Typical tungsten etch rates for the compositions of the second aspect are in the range of about 1-5 Å/min at 45° C., a rate that can be further reduced by adding corrosion inhibitors.

The compositions of the first or second aspect can further comprise platinum and nickel, wherein the platinum and nickel is present as ions complexed in the composition.

The compositions of the first and second aspect described herein are easily formulated by simple addition of the respective ingredients and mixing to homogeneous condition. Furthermore, the compositions may be readily formulated as single-package formulations or multi-part formulations that are mixed at or before the point of use, e.g., the individual parts of the multi-part formulation may be mixed at the tool or in a storage tank upstream of the tool. The concentrations of the respective ingredients may be widely varied in specific multiples of the composition, i.e., more dilute or more concentrated, and it will be appreciated that the compositions described herein can variously and alternatively comprise, consist or consist essentially of any combination of ingredients consistent with the disclosure herein. Further, the compositions of the first and second aspect can be recycled.

Accordingly, another aspect relates to a kit including, in one or more containers, one or more components adapted to form the compositions described herein. In one embodiment, the kit may include, in one or more containers, at least one acid, at least one oxidizing agent, at least one complexing agent, at least one solvent, and optionally at least one corrosion inhibitor, for combining with additional solvent at the fab or the point of use. In another embodiment, the kit may include, in one or more containers, at least one acid, at least one complexing agent, at least one solvent, and optionally at least one corrosion inhibitor, for combining with at least one oxidizing agent at the fab or the point of use. In another embodiment, the kit may include, in one or more containers, at least one complexing source (i.e., at least one halide ion salt), at least one oxidizing agent (i.e., halogen and/or interhalogen compound), optionally at least one acid, and at least one solvent, for combining with additional solvent at the fab or the point of use. In yet another embodiment, the kit may include, in one or more containers, at least one complexing source (i.e., at least one halide ion salt), optionally at least one acid, and at least one solvent, for combining with at least one oxidizing agent (i.e., halogen and/or interhalogen compound) at the fab or the point of use. The containers of the kit must be suitable for storing and shipping said cleaning compositions, for example, NOWPak® containers (Advanced Technology Materials, Inc., Danbury, Conn., USA).

The one or more containers which contain the components of the composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended cleaning composition to a process tool.

Substantially chemically inert, impurity-free, flexible and resilient polymeric film materials, such as high density polyethylene, are preferably used to fabricate the liners for said one or more containers. Desirable liner materials are processed without requiring co-extrusion or barrier layers, and without any pigments, UV inhibitors, or processing agents that may adversely affect the purity requirements for components to be disposed in the liner. A listing of desirable liner materials include films comprising virgin (additive-free) polyethylene, virgin polytetrafluoroethylene (PTFE), polypropylene, polyurethane, polyvinylidene chloride, polyvinylchloride, polyacetal, polystyrene, polyacrylonitrile, polybutylene, and so on. Preferred thicknesses of such liner materials are in a range from about 5 mils (0.005 inch) to about 30 mils (0.030 inch), as for example a thickness of 20 mils (0.020 inch).

Regarding the containers for the kits, the disclosures of the following patents and patent applications are hereby incorporated herein by reference in their respective entireties: U.S. Pat. No. 7,188,644 entitled “APPARATUS AND METHOD FOR MINIMIZING THE GENERATION OF PARTICLES IN ULTRAPURE LIQUIDS;” U.S. Pat. No. 6,698,619 entitled “RETURNABLE AND REUSABLE, BAG-IN-DRUM FLUID STORAGE AND DISPENSING CONTAINER SYSTEM;” and PCT/US08/63276 entitled “SYSTEMS AND METHODS FOR MATERIAL BLENDING AND DISTRIBUTION” filed on May 9, 2008 in the name of Advanced Technology Materials, Inc.

In use of the compositions for removing NiPt (1-25% Pt) material from microelectronic devices having same thereon, the compositions typically are contacted with the device for a time of from about 10 sec to about 180 minutes, preferably about 1 minute to about 5 minutes, at temperature in a range of from about 15° C. to about 100° C., preferably about 30° C. to about 70° C. Such contacting times and temperatures are illustrative, and any other suitable time and temperature conditions may be employed that are efficacious to at least partially remove the NiPt (1-25% Pt) material from the device. Such contacting times and temperatures are illustrative, and any other suitable time and temperature conditions may be employed that are efficacious to at least partially remove NiPt (1-25%) material from the device, within the broad practice of the method. “At least partially remove” corresponds to the removal of at least 85% of the NiPt (1-25% Pt) material prior to removal, more preferably at least 90%, even more preferably at least 95%, and most preferred at least 99%. Advantageously, the compositions of the first and second aspect effectively and efficiently remove NiPt (1-25% Pt) material from the surface of a microelectronic device having same thereon without substantially removing other materials present on the microelectronic device such as metal gate materials (e.g., TiN, Al and W) and silicided NiPt (i.e., NiₓPt₁₋ₓSi).

It should be appreciated that the compositions of the first and second aspects can be used to selectively remove other noble metal containing alloys including, but not limited to, NiPd, NiRu, NiIr, NiRh, NiRe, CoPt, CoPd, CoRu, CoIr, CoRh, and CoRe.

Following the achievement of the desired removal action, the composition may be readily removed from the device to which it has previously been applied, as may be desired and efficacious in a given end use application of the compositions described herein. Preferably, the rinse solution for the composition includes deionized water. Thereafter, the device may be dried using nitrogen or a spin-dry cycle.

Yet another aspect relates to the improved microelectronic devices made according to the methods described herein and to products containing such microelectronic devices. Preferably, the microelectronic device comprises the silicide NiₓPt₁₋ₓSi.

A still further aspect relates to methods of manufacturing an article comprising a microelectronic device, said method comprising contacting the microelectronic device with a composition for sufficient time to remove a NiPt (1-25% Pt) material from the microelectronic device having said material thereon, and incorporating said microelectronic device into said article, using a composition described herein. Preferably, the microelectronic device comprises the silicide NiₓPt₁₋ₓSi.

Another aspect relates to an article of manufacture comprising a composition, a microelectronic device wafer, and material selected from the group consisting of NiPt (1-25%), NiₓPt₁₋ₓSi, and combinations thereof, wherein the composition comprises at least one acid, at least one oxidizing agent, at least one complexing agent, at least one solvent, and optionally at least one corrosion inhibitor. Alternatively, the composition comprises at least one complexing source (i.e., at least one halide ion salt), at least one oxidizing agent (i.e., halogen and/or interhalogen compound), optionally at least one acid, and at least one solvent.

The features and advantages are more fully shown by the illustrative examples discussed below.

### EXAMPLE 1

All of the compositions of the first aspect shown in Table 1 (with the balance being water) were tested at the temperature indicated for the time required to reliably fully remove 200 Å of NiPt (10% Pt) that was deposited on SiO₂ to avoid silicide formation. A slightly diluted Aqua regia formulation was provided for comparison.

TABLE 1

| Formu- | Temper- | Time/ | Nitric acid/ | MSA/ | HCl/ | Urea hydrogen | Ammonium | Dimethyl- |
|---|---|---|---|---|---|---|---|---|
| lation | ature/° C. | minutes | wt. % | wt. % | wt. % | peroxide/wt. % | chloride/wt. % | glyoxime/wt. % |
| A | 65 | 2.5 | | 37 | | 14.8 | 0.09 | 0.14 |
| B | 55 | 2 | | 40 | | 9 | 0.1 | 0.15 |
| C | 55 | 4 | 2.5 | | | | 1.0 | |
| D | 55 | 4 | 1.5 | | | | 0.9 | |
| E | 55 | 4 | 5.0 | | | | 0.25 | |
| Aqua regia | 40 | 8 | 10 | | 50 | | | |

| | Benzyl- | | Time to fully etch/min | | | | |
|---|---|---|---|---|---|---|---|
| Formu- | phosphonic | Aspartic | 200 Å NiPt | 70 Å NiPt | Amount etched/Å | | |
| lation | acid/wt. % | acid/wt. % | (10%) on SiO₂ | (10%) on silicide | W | Al | TiN |
| A | | 1.5 | <2.5 | 2.5 | 1060 | <75 | 98 |
| B | | 1.5 | <2 | 2 | 434 | <75 | 32 |
| C | | | <4 | <4 | <10 | 136 | 2 |
| D | | | <4 | <4 | <10 | 572 | 2 |
| E | 0.10 | | <4 | 2 | 8 | <10 | <2 |
| Aqua regia | | | <8 | <8 | 231 | >>2700 | >>50 |

It can be seen that formulation A and B etch NiPt very fast without damaging NiPt silicide and have low Al etch rates. However they have very high W and TiN etch rates. Formulations C and D are dilute nitric acid/ammonium chloride mixtures. They have lower NiPt (10%) removal rates, and poor Al compatibility but with better TiN and W compatibility. Formulation E has an added Al corrosion inhibitor. This formulation has very good compatibility with TiN, W and Al with a removal rate sufficient for a 4 minute process.

### EXAMPLE 2

All of the compositions of the first aspect shown in Table 2 were tested at the temperature indicated for the time required to reliably fully remove 200 Å of NiPt (10% Pt) that was deposited on SiO₂ to avoid silicide formation. A slightly diluted Aqua regia formulation was provided for comparison.

TABLE 2

| | Process | | | Formulation (mass %) | | | | | | |
|---|---|---|---|---|---|---|---|---|---|---|
| Formu- | | patterned | blanket | | | Bromo- | Chloro- | | | |
| lation | T | removal time | removal time | Ammonium | | succinimide | succinimide | | Ammonium | Ammonium |
| Name | (° C.) | (minutes) * | (minutes) | persulfate | Bromine | (99%) | (98%) | Water | Chloride | Bromide |
| F | 35 | <20 | <0.5 | | 0.3 | | | 92.7 | 2 | 2.5 |
| G | 35 | <4 | <0.5 | | | 4 | 0.4 | 81.1 | 2 | 10 |
| H | 35 | <4 | <0.5 | 5 | | | | 69.5 | 5 | |
| Aqua | 40 | <8 | <0.5 | | | | | | | |
| Regia | | | | | | | | | | |
| I | | | | | | 4.6 | | 80.9 | 2 | 10 |
| J | | | | | | 4 | 0.4 | 81.1 | 2 | 10 |
| K | | | | | | 4 | 0.4 | 83.1 | | 10 |
| L | | | | | | 4 | 0.4 | 87.6 | 0.5 | 5 |
| M | | | | | | 4 | 0.4 | 82.6 | 0.5 | 10 |
| N | | | | | | 4 | 0.4 | 86.1 | 2 | 5 |
| O | | | | | | 4 | 0.4 | 90.6 | 2.5 | |
| P | | | | | | 0.67 | | 92.33 | 2 | 2.5 |
| Q | | | | | | 0.67 | | 89.83 | 2 | 5 |
| R | | | | | | 0.81 | | 90.94 | 2 | 3.75 |
| S | | | | | | 0.95 | | 92.05 | 2 | 2.5 |
| T | | | | | | 0.95 | | 89.55 | 2 | 5 |
| U | | | | | | 0.67 | 0.13 | 92.2 | 2 | 2.5 |
| V | | | | | | 0.81 | 0.13 | 90.81 | 2 | 3.75 |
| W | | | | | | 0.95 | 0.13 | 89.42 | 2 | 5 |
| X | | | | | 0.3 | | | 92.7 | 2 | 2.5 |
| Y | | | | | 0.9 | | | 89.6 | 2 | 5 |
| Z | | | | | | 2 | | 88.5 | 2 | 5 |
| AA | | | | | 1.8 | | | 83.7 | 2 | 10 |
| BB | | | | | | 4 | | 81.5 | 2 | 10 |
| CC | | | | | | | | 69.50 | 5 | |

| | Formulation (mass %) | | | | | | Etch Rates in Å/minute | | | | | |
|---|---|---|---|---|---|---|---|---|---|---|---|---|
| Formu- | Imino- | | Methane- | Sulfuric | Conc. | Conc. | NiPt(15%)/ | | NiPt(10%) | NiPt(10%) | | |
| lation | diacetic | | sulfonic | Acid | Nitric Acid | HCl | oxide | NiPt(10%) | SiGe(20%) | SiGe(35%) | | |
| Name | Acid | Sucrose | Acid | (conc) | (wt %) | (wt %) | annealed | silicide | silicide | silicide | W | TiN |
| F | | | 2.5 | | | | >500 | <1 | <1 | 1.8 | 2.5 | <0.05 |
| G | | | 2.5 | | | | >500 | <1 | <1 | | 2.3 | 0.23 |
| H | 0.5 | 10 | | 10 | | | >500 | <1 | <1 | 0.16 | 2.4 | <0.2 |
| Aqua | | | | | 10 | 50 | >200 | 15 | <1 | 5 | 29 | >50 |
| Regia | | | | | | | | | | | | |
| I | | | 2.5 | | | | | | | | | |
| J | | | | 2.5 | | | | | | | | |
| K | | | | 2.5 | | | | | | | | |
| L | | | | 2.5 | | | | | | | | |
| M | | | 2.5 | | | | | | | | | |
| N | | | 2.5 | | | | | | | | | |
| O | | | 2.5 | | | | | | | | | |
| P | | | 2.5 | | | | | | | | | |
| Q | | | 2.5 | | | | | | | | | |
| R | | | 2.5 | | | | | | | | | |
| S | | | 2.5 | | | | | | | | | |
| T | | | 2.5 | | | | | | | | | |
| U | | | 2.5 | | | | | | | | | |
| V | | | 2.5 | | | | | | | | | |
| W | | | 2.5 | | | | | | | | | |
| X | | | 2.5 | | | | | | | | | |
| Y | | | 2.5 | | | | | | | | | |
| Z | | | 2.5 | | | | | | | | | |
| AA | | | 2.5 | | | | | | | | | |
| BB | | | 2.5 | | | | | | | | | |
| CC | 0.50 | 10 | | 10 | 5 | | | | | | | |

It can be seen that formulation F, G, and H etch NiPt very fast with good W and TiN compatibility compared to Aqua Regia. Formulation F requires long process times (20 minutes) on patterned wafers. Formulations G and H allow for shorter processing times while still maintaining W and TiN compatibility.

### EXAMPLE 3

The inventors formulated and discovered that compositions of the second aspect I and J below etched typical annealed Ni-10% Pt and Ni-15% Pt films which are about 80-120 Å thick at 45° C., with low corrosion of W, Al and TiN.

Formulation I: 0.5 wt % iodine, 6 wt % ammonium iodide, 5 wt % MSA, 88.5 wt % water. Removed the films in 60s @45° C.
Formulation J: 0.5 wt % iodine, 2 wt % ammonium iodide, 5 wt % MSA, 92.5 wt % water. Removed the films in 90s @45° C.

### EXAMPLE 4

When the NiPt film is annealed without a capping layer, it becomes less soluble in the triiodide etching composition. Although not wishing to be bound by theory, it is thought that the lowered solubility is a result of the triiodide having to break through a surface layer of the NiPt film. In order to overcome this problem, a nickel complexing agent that doesn't react with iodine was added to the triiodide solution. Oxalic acid is actually more active at somewhat higher pH (3-4), which can be achieved by the controlled addition of a base such as ammonia, so that the acid is largely deprotonated and more available for complexation. Compositions of the second aspect K and L below etched typical annealed Ni-10% Pt and Ni-15% Pt films which are about 80-120 Å thick at 45° C., with low corrosion of Al and TiN.

Formulation K: 1 wt % iodine, 2 wt % ammonium iodide, 6 wt % oxalic acid, 91 wt % water. Removed the films in 90s @45° C.
Formulation L: 1 wt % iodine, 2 wt % ammonium iodide, 6 wt % oxalic acid, 91 wt % water pH adjusted with NH4OH to pH=4. Removed the films in 90s @45° C.

An unfortunate side effect of the inclusion of oxalic acid is a substantial increase in tungsten etch rates, especially at the higher pH. To overcome this deficiency, the etching composition can be optimized (in particular, using oxalic acid at <1% and/or low pH) to help minimize this problem.

### EXAMPLE 5

Etching compositions of the second aspect were formulated and tested with the aforementioned 80-100 Å Ni-10% Pt film at the indicated temperatures and time:

Formulation M: 48.8 wt % acetic acid, 39 wt % water, 9.5 wt % NH4Cl, 2.4 wt % ICl. Removed the films in 120 sec at room temperature (22±1° C.)
Formulation N: 20 wt % ammonium bromide, 1.96 wt % IBr, 78.04 wt % water. Removed the films in 240 sec at 45° C.
Formulation O: 19 wt % ammonium bromide, 1.86 wt % IBr, 5 wt % MSA, 74.14 wt % water. Removed the films in 180 sec at 45° C.
Formulation P: 4 wt % ammonium bromide, 1 wt % IBr, 50 wt % acetic acid, 45 wt % water. Removed the films in 180 sec at 45° C.
Formulation Q: 20 wt % ammonium bromide, 1 wt % MSA, 0.5 wt % ammonium persulfate (to form 0.35% bromine), 78.5 wt % water. Removed the films in 30 sec at 45° C.
Formulation R: 20 wt % ammonium bromide, 6 wt % acetic acid, 0.5 wt % ammonium persulfate (to form 0.35% bromine), 73.5 wt % water. Removed the films in 90 sec at 45° C.
Formulation S: 4 wt % ammonium bromide, 3.5 wt % nitric acid (to form 4.4 wt % bromine with 1.3 wt % excess NH4Br), 92.5 wt % water. Removed the films in 60 sec at 45° C.

Accordingly, the applicants have verified that IBr, ICl and Br₂ are all capable of etching the annealed Ni-10% Pt films in ≦3 minutes at 45° C.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art, based on the disclosure herein. The invention therefore is to be broadly construed, as encompassing all such variations, modifications and alternative embodiments within the spirit and scope of the claims hereafter set forth.

1. A method of removing NiPt (1-25% Pt) from a microelectronic device comprising same, said method comprising contacting the NiPt (1-25% Pt) with a composition to at least partially remove the NiPt (1-25%), wherein the composition comprises at least one oxidizing agent, at least one complexing agent, and at least one solvent.

2. The method of claim 1, wherein metal gate material and silicided NiPt are not substantially removed using the composition, wherein the metal gate material comprises a species selected from the group consisting of Ti, Ta, W, Mo, Ru, Al, La, titanium nitride, tantalum nitride, tantalum carbide, titanium carbide, molybdenum nitride, tungsten nitride, ruthenium (IV) oxide, tantalum silicon nitride, titanium silicon nitride, tantalum carbon nitride, titanium carbon nitride, titanium aluminide, tantalum aluminide, titanium aluminum nitride, tantalum aluminum nitride, lanthanum oxide, or combinations thereof.

3. (canceled)

4. The method of claim 1, wherein the at least one oxidizing agent comprises a species selected from the group consisting of bromine, ozone, nitric acid, bubbled air, cyclohexylaminosulfonic acid, hydrogen peroxide, FeCl₃ (both hydrated and unhydrated), oxone (2KHSO₅.KHSO₄.K₂SO₄), oxone tetrabutylammonium salt, iodic acid, periodic acid, permanganic acid, chromium (III) oxide, ammonium cerium nitrate, methylmorpholine-N-oxide, trimethylamine-N-oxide, triethylamine-N-oxide, pyridine-N-oxide, N-ethylmorpholine-N-oxide, N-methylpyrrolidine-N-oxide, N-ethylpyrrolidine-N-oxide, nitrobenzoic acid, ammonium peroxomonosulfate, ammonium chlorite, ammonium chlorate, ammonium iodate, ammonium perborate, ammonium perchlorate, ammonium periodate, ammonium persulfate, ammonium hypochlorite, sodium persulfate, sodium hypochlorite, potassium iodate, potassium permanganate, potassium persulfate, potassium persulfate, potassium hypochlorite, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, tetrabutylammonium peroxomonosulfate, peroxomonosulfuric acid, ferric nitrate, urea hydrogen peroxide, peracetic acid, sodium nitrate, potassium nitrate, ammonium nitrate, sulfuric acid, N-chlorosuccinimide, N-bromosuccinimide, N-halophthlamides, N-haloglutarimides, N,N-dichlorobenzenesulfonamide, N,N-dichlorotoluenesulfonamide, N-chlorobenzenesulfonamide, N-chlorotoluenesulfonamide, chlorine, chlorine dioxide, and combinations thereof.

5. The method of claim 1, wherein the at least one oxidizing agent comprises a species selected from the group consisting of sulfuric acid, bromosuccinimide, chlorosuccinimide, ammonium persulfate, ammonium nitrate, nitric acid and combinations thereof.

6. The method of claim 1, wherein the at least one complexing agent comprises a species selected from the group consisting of acetylacetonate, 1,1,1-trifluoro-2,4-pentanedione, 1,1,1,5,5,5-hexafluoro-2,4-pentanedione, formates, acetates, bis(trimethylsilylamide) tetramer, glycine, serine, proline, leucine, alanine, asparagine, aspartic acid, glutamine, valine, lysine, citric acid, acetic acid, maleic acid, oxalic acid, malonic acid, succinic acid, phosphonic acid, hydroxyethylidene diphosphonic acid (HEDP), 1-hydroxyethane-1,1-diphosphonic acid, nitrilo-tris(methylenephosphonic acid), iminodiacetic acid, etidronic acid, ethylenediamine, ethylenediaminetetraacetic acid (EDTA), (1,2-cyclohexylenedinitrilo)tetraacetic acid (CDTA), uric acid, tetraglyme, pentamethyldiethylenetriamine (PMDETA), 1,3,5-triazine-2,4,6-thithiol trisodium salt solution, 1,3,5-triazine-2,4,6-thithiol triammonium salt solution, sodium diethyldithiocarbamate, disubstituted dithiocarbamates, ammonium sulfate, monoethanolamine (MEA), Dequest 2000, Dequest 2010, Dequest 2060s, diethylenetriamine pentaacetic acid, propylenediamine tetraacetic acid, 2-hydroxypyridine 1-oxide, ethylendiamine disuccinic acid (EDDS), N-(2-hydroxyethyl)iminodiacetic acid (HEIDA), sodium triphosphate penta basic, hydrochloric acid, sulfuric acid, dimethylglyoxime, ammonium chloride, ammonium bromide, sodium chloride, lithium chloride, potassium chloride, sulfonates, nitrates, sulfates, methanesulfonic acid (MSA), ethanesulfonic acid, 2-hydroxyethanesulfonic acid, n-propanesulfonic acid, isopropanesulfonic acid, isobutenesulfonic acid, n-butanesulfonic acid, and n-octanesulfonic acid, and combinations thereof.

7. The method of claim 1, wherein the at least one complexing agent comprises a species selected from the group consisting of ammonium chloride, ammonium bromide, iminodiacetic acid, or a combination thereof.

8. The method of claim 1, wherein the composition further comprises at least one acid, wherein the at least one acid comprises a species selected from the group consisting of nitric acid, hydrochloric acid, sulfuric acid, hydrobromic acid, hydroiodic acid, perchloric acid, phosphoric acids, methanesulfonic acid, 1-hydroxyethane 1,1-diphosphonic acid (HEDP), decylphosphonic acid, dodecylphosphonic acid (DDPA), tetradecylphosphonic acid, hexadecylphosphonic acid, bis(2-ethylhexyl)phosphate, octadecylphosphonic acid, and combinations thereof.

9. (canceled)

10. The method of claim 8, wherein the at least one acid comprises hydrochloric acid, sulfuric acid or methanesulfonic acid.

11. The method of claim 1, wherein the composition further comprises at least one corrosion inhibitor, at least one monosaccharide, at least one polysaccharide, at least one sugar alcohol, at least one non-ionic surfactant, at least one co-solvent, and any combination thereof.

12. (canceled)

13. (canceled)

14. The method of claim 1, wherein the composition has a pH in a range from about −1 to about 7.

15. The method of claim 1, wherein the oxidizing agent comprises a halogen or an interhalogen compound, wherein the halogen comprises iodine, bromine, or chlorine and wherein the interhalogen compound is selected from the group consisting of IBr and ICl.

16. (canceled)

17. The method of claim 15, wherein the iodine is generated in situ.

18. (canceled)

19. The method of claim 15, wherein the at least one complexing agent comprises a halide species, wherein the at least one halide comprises a species selected from the group consisting of NH₄Cl, NH₄Br, NH₄I, HCl, HBr, HI, KI, Nal, and quaternary ammonium halides having the formula NR¹R²R³R⁴X, wherein X is Cl, Br, or I and R¹, R², R³ and R⁴ may be the same as or different from one another and are selected from the group consisting of hydrogen, straight-chained or branched C₁-C₆ alkyl, and substituted or unsubstituted C₆-C₁₀ aryl, with the proviso at least one of R¹, R², R³ or R⁴ has to be a component other than hydrogen.

20. (canceled)

21. The method of claim 19, wherein the halide species comprises ammonium iodide.

22. (canceled)

23. (canceled)

24. The method of claim 15, further comprising at least one acid, wherein the at least one acid comprises a species selected from the group consisting of methanesulfonic acid, oxalic acid, sulfuric acid, HCl, HBr, HI, citric acid, tartaric acid, picolinic acid, succinic acid, acetic acid, and combinations thereof.

25. (canceled)

26. The method of claim 24, wherein the at least one acid comprises methanesulfonic acid or oxalic acid.

27. The method of claim 15, wherein the at least one solvent comprises water or acetic acid.

28. (canceled)

29. The method of claim 15, wherein the composition further comprises at least one corrosion inhibitor, at least one monosaccharide, at least one polysaccharide, at least one sugar-alcohol, or any combination thereof.

30. The method of claim 1, wherein the composition comprises a species selected from the group consisting of triiodide ion, a tribromide ion, and a trichloride ion.

31. The method of claim 30, wherein the triiodide source is tetrabutylammonium triiodide or cesium triiodide, and the tribromide source is tritetrabutylammonium tribromide, pyridinium tribromide, trimethylphenylammonium tribromide, or 1-butyl-3-methylimidazolium tribromide.

32. (canceled)
